(19) United States
(12) Patent Application Publication
(10) Pub. No.: US 2008/0282120 A1
(43) Pub. Date: Nov. 13, 2008

(54) Memory structure, repair system and method for testing the same

(75) Inventors: Chun-Yu Liao, Taichung (TW); Tzung-Shen Chen, Taoyuan (TW)

Correspondence Address: BIRCH STEWART KOLASCH & BIRCH, PO BOX 747, FALLS CHURCH, VA, 22040-0747, US

(73) Assignee: MACRONIX INTERNATIONAL CO., LTD.

(21) Appl. No.: 11/798,292

(22) Filed: May 11, 2007

(51) Int. Cl. G06F 11/00; G11C 29/00

(52) U.S. Cl. 714/719; 714/764; 714/E11.001

(57) ABSTRACT

A memory structure is provided. The memory structure includes a memory array, an error correct code (ECC) unit, and a comparator. The memory array includes at least one memory cell being written and storing at least one original data. The ECC unit is for reading at least one tested data from the at least one memory cell, correcting the at least one tested data when there is an error occurred in the at least one tested data and outputting at least one ECC data accordingly. The comparator is for determining whether the at least one original data is substantially the same as the at least one ECC data or not and outputting an output signal indicating whether the at least one memory cell passes or fails.

### BACKGROUND OF THE INVENTION

1. Field of the Invention

The invention relates in general to a memory structure, and more particularly to a memory structure capable of improving the yield and being tested quickly.

2. Description of the Related Art

The manufacturing of memories includes a step of testing the data stored in the memories. FIG. 1 illustrates a memory array 110 and the tester 120 for testing the memory array 110. The tester 120 includes a comparator 121 and a data buffer memory 122. An original data D0 (not shown) is written into each test-required memory cell in the memory array 120. The data buffer memory 122 also stores a reference data D2, which is a correct copy of the original data D0. When the input address AI is supplied into the memory array 110 and the data buffer memory 122, a tested data D1 read from the memory cell corresponding to the input address AI in the memory array 110 and the corresponding reference data D2 in the data buffer memory 122 are respectively output to the comparator 121. The comparator 121 compares the corresponding reference data D2 with the tested data D1 and outputs an output signal So to indicate whether the original data D0 is correctly stored in the memory cell corresponding to the input address AI, so as to determine whether the memory cell is correct or fail.

However, as the storing size of the memory array increases, testing memory cells one by one in the memory array with the conventional tester becomes very time-consuming. In addition, the storing size of the data buffer memory 122 is also increased to a prohibitive degree. Thus, it is desired to provide a memory structure capable of being tested in a more efficient way during its manufacturing.

### SUMMARY OF THE INVENTION

The invention is directed to a memory structure. During testing the memory cells of the memory structure, as long as the ECC unit thereof is able to correct the error occurred in the tested data read from the memory cells, the memory cells are determined as pass. Therefore, the yield is improved by employing the memory structure.

According to (a first aspect of) the present invention, a memory structure is provided. The memory structure includes a memory array, an error correct code (ECC) unit, and a comparator. The memory array includes at least one memory cell being written and storing at least one original data. The ECC unit is for reading at least one tested data from the at least one memory cell, correcting the at least one tested data when there is an error occurred in the at least one tested data and outputting at least one ECC data accordingly. The comparator is for determining whether the at least one original data is substantially the same as the at least one ECC data or not and outputting an output signal indicating whether the at least one memory cell passes or fails.

According to (a second aspect of) the present invention, a method for testing at least one memory cell of a memory structure memory structure is provided. The method includes: firstly, write at least one original data into the at least one memory cell. Then, read at least one tested data from the at least one memory cell and perform an error correction code (ECC) operation on the at least one tested data and outputting at least one ECC data accordingly. Next, determine whether the at least one ECC data is substantially the same as the at least one original data, so as to determine whether the at least one memory cell passes or fails.

The invention will become apparent from the following detailed description of the preferred but non-limiting embodiments. The following description is made with reference to the accompanying drawings.

### BRIEF DESCRIPTION OF THE DRAWINGS

FIG. 1 illustrates a memory array and a tester for testing the memory array.

FIG. 2 is a block diagram of the memory structure according to the embodiment of the invention.

FIG. 3 illustrates a block diagram of parallel-testing a number of memories having the memory structure according to the embodiment of the invention.

FIG. 4 is the flow chart of the method for testing the memory structure according to the embodiment of the invention.

### DETAILED DESCRIPTION OF THE INVENTION

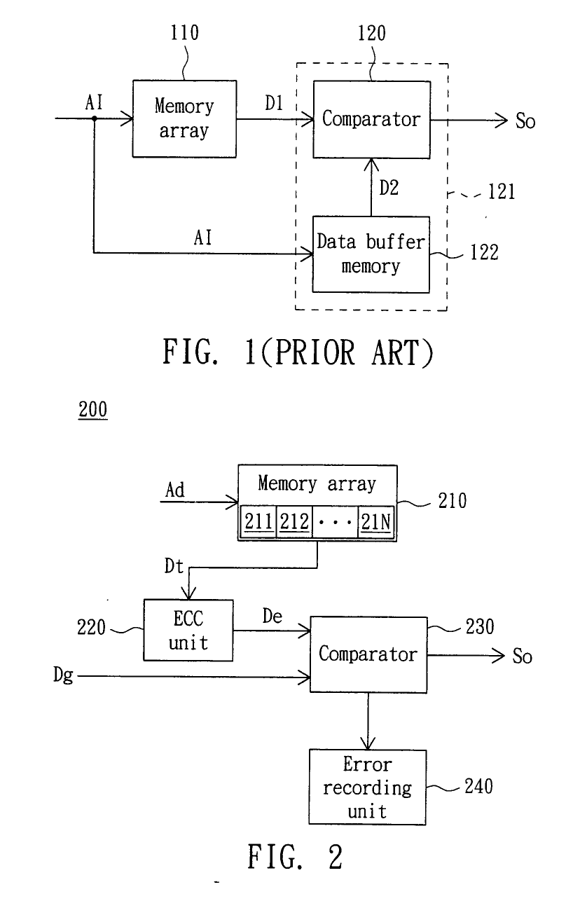

FIG. 2 is a block diagram of the memory structure according to the embodiment of the invention. Referring to FIG. 2, the memory structure 200 includes a memory array 210, an error correct code (ECC) unit 220 and a comparator 230.

The memory array 210 includes memory cells 211 to 21N. N is a positive integer. An original data Dg (not shown) is written into each memory cell according to an input address Ad. The error correction code (ECC) unit 220 is used to read the data stored in the memory cells 211 to 21N, which are defined as the tested data Dt, perform an ECC operation to correct the tested data Dt when there is an error occurred in the tested data Dt and output an ECC data De accordingly.

The comparator 230 compares the ECC data De with the original data Dg and outputs an output signal So indicating whether the ECC data De is substantially the same as the original data Dg, so as to determine whether the memory cells 211 to 21N are correctly accessed with the original data Dg or not, in order to determine whether the memory cells 211 to 21N are correct or not.

When the ECC data De is substantially equal to the original data Dg, it implies that the tested data Dt read from the memory cells 211 to 21N are correct, or the tested data Dt is able to be successfully corrected by the ECC unit 220 when there is an error occurred. The comparator 230 then outputs the output signal So indicating the memory cells 211 to 21N pass. That is, the memory cells 211 to 21N pass as long as the ECC unit 220 can successfully correct the error occurred in the tested data Dt read from the memory cells.

When the ECC data De is not substantially equal to the original data Dg, it implies that the tested data Dt is not correctly read from the memory cell and is not successfully corrected by the ECC unit 220. Therefore, the comparator 230 outputs the output signal So indicating the memory cells 211 to 21N fails. That is, the memory cells 211 to 21N fail when there is error occurred in the tested data Dt, and even the ECC unit 220 is unable to correct the tested data Dt successfully.

For example, when the ECC unit 220 is used to perform a 1-bit ECC operation, the 1-bit error occurred in the tested data Dt is able to be corrected thereby. That is, the 1-bit error for the memory cells 211 to 21N is tolerable. Therefore the memory cells 211 to 21N are determined as pass even there is the 1-bit error occurred. However, when there is an error more than one bit occurred in the tested data Dt, the 1-bit ECC unit 220 is unable to correct it. The memory cells 211 to 21N are therefore determined as fail. With 1-bit ECC circuit, the program yield and program speed is improved about 5%-10%.

The memory structure further includes an error recording unit 240. In the embodiment of the invention, the error recording unit 240 records the address of the fail memory cell. Another correct memory cell is used to replace the fail memory cell. Thus, when one desires to access the recorded memory cell, the replacing correct memory cell is accessed.

In the embodiment of the invention, the memory cells 211 to 21N are located in a memory row of the memory array 210. When the ECC data De is not substantially equal to the original data Dg, that is, too many error bits occurs in the memory row and can't be corrected and recovered by the ECC operation, the address of the memory row could be recorded as fail in the error recording unit 240. The memory array 210 can be implemented as a repair system. A repair row in the memory array 210 could be used to replace the memory row. Another original data is written into the repair row to determine whether the repair row is correct or not. When the fail memory row is to be accessed in the application of the memory, it is redirected to the repair row.

Similarly, when memory cells located in a memory column of the memory array 210 are determined as fail, the address of the memory column could also be recorded as fail in the error recording unit 240. A repair column in the memory array 210 could also be used to replace the memory column. Another original data is written into the repair column to determine whether the repair column is correct or not. When the fail memory column is to be accessed in the application of the memory, it is redirected to the repair column.

In the embodiment of the invention, each of memory cells 211 to 21 N is tested by storing the original data Dg equal to 0 and 1, so as to verify if they are capable of being accessed with 0 as well as 1 correctly.

The original data Dg is written to the memory array by a tester. The tester also receives the output signal So in order to determine whether the tested memory cells pass or fail.

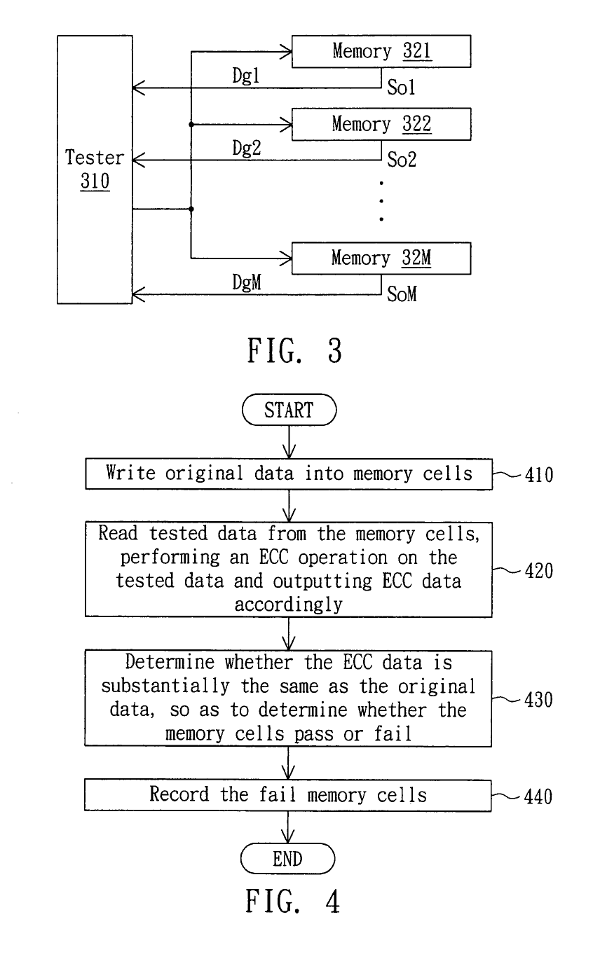

FIG. 3 illustrates a block diagram of parallel-testing a number of memories 321 to 32M having the memory structure 200, where M is a positive integer. The tester 310 input the original data Dg1 to DgM respectively into the memories 321 to 32M to test the memory arrays thereof. The memory cells in the memory arrays thereof are tested as described before. The output signals So1 to SoM indicating whether the memory cells in the memory arrays of the memories 321 to 32M pass or fail are respectively outputted to the tester 310.

During the test of the memories, only one testing pin in the tester 310 is needed to receive the output signal for each memory. The tester 310 is therefore capable of testing more memories at the same time. In comparison to the test of the memory having conventional memory structure, where the memory cells are one by one tested, one testing pin in the tester 310 is only used to receive the output signal corresponding to one single memory cell. Thus, more testing pins are needed for testing a memory having the conventional memory structure. Therefore, the tester 310 can parallel-test more memories having the memory structure according to the embodiment of the invention, so as to speed up the manufacturing.

FIG. 4 is the flow chart of the method for testing the memory structure 200 according to the embodiment of the invention. Firstly, in the step 410, write the original data Dg into the memory cells 211 to 21N. Next, in the step 420, read the tested data Dt from the memory cell 211 to 21N, and perform the ECC operation on the tested data Dt and output an ECC data accordingly.

Afterwards, in the step 430, determining whether the ECC data De is substantially the same as the original data Dg, so as to determine whether the memory cells 211 to 21N pass or fail. Then in the step 440, record the address of the fail memory cell when the memory cells 211 to 21N are determined as fail.

During testing the memory cells of the memory structure according to the embodiment, the memory cells are determined as pass, as long as the ECC unit thereof is able to correct the error occurred in the tested data read from the memory cells. Therefore, the yield is improved by employing the memory structure.

Besides, one memory having the memory structure needs only one testing pin in the tester for receiving the output signal indicating fail or pass for memory cells in the memory. Therefore, more memories having the memory structure can be parallel-tested by the tester. Thus, by applying the memory structure according to the embodiment of the invention, the test of the memories is speeded up significantly, so as to improve the efficiency of the manufacturing.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A memory structure, comprising:
a memory array, comprising at least one memory cell being written at least one original data;
an error correct code (ECC) unit, for reading at least one tested data from the at least one memory cell, correcting the at least one tested data when there is an error occurred in the at least one tested data and outputting at least one ECC data accordingly; and
a comparator, for determining whether the at least one original data is substantially the same as the at least one ECC data or not and outputting an output signal indicating whether the at least one memory cell passes or fails.

2. The memory structure according to claim 1, wherein the memory structure further comprises an error recording unit, for recording the at least one memory cell when the at least one memory cell fails.

3. The memory structure according to claim 1, wherein the memory structure further comprises an error recording unit, the at least one memory cells is located a memory row or a memory column of the memory array, the memory row or the memory column is recorded in the error recording unit when the at least one memory cell fails.

4. The memory structure according to claim 3, wherein the memory row or the memory column recorded in the error recording unit is replaced by a repair row or a repair column of the memory array.

5. The memory structure according to claim 1, wherein the at least one original data is written into the at least one memory cell by a tester, the comparator comparing the at least one original data transferred from the tester with the at least one ECC data.

6. The memory structure according to claim 1, wherein the ECC unit is a one-bit ECC unit.

7. A method for testing at least one memory cell of a memory structure, comprising:
writing at least one original data into the at least one memory cell;
reading at least one tested data from the at least one memory cell, performing an error correction code (ECC) operation on the at least one tested data and outputting at least one ECC data accordingly; and
determining whether the at least one ECC data is substantially the same as the at least one original data, so as to determine whether the at least one memory cell passes or fails.

8. The method according to claim 7, further comprising:
recording the at least one memory cell when the at least one memory cell fails.

9. The method according to claim 7, wherein the at least one memory cell is located at a memory row or a memory column of the memory array, the method further comprises:
recording the memory row or the memory column when the at least one memory cell is determined as fail.

10. The method according to claim 7, wherein in the step of performing the ECC operation, correct the at least one tested data when there is error occurred in the at least one tested data, and then output the at least one ECC data accordingly.
